(19) United States
(12) Patent Application Publication
(10) Pub. No.: US 2015/0054075 A1
(43) Pub. Date: Feb. 26, 2015

(54) SEMICONDUCTOR DEVICE

(71) Applicants: Tadahiro Ohmi, Sendai-shi (JP); Hiroaki Tanaka, Sendai-shi (JP)

(72) Inventors: Tadahiro Ohmi, Sendai-shi (JP); Hiroaki Tanaka, Sendai-shi (JP)

(73) Assignee: TOHOKU UNIVERSITY, Sendai-shi (JP)

(21) Appl. No.: 14/501,244

(22) Filed: Sep. 30, 2014

Related U.S. Application Data
(63) Continuation of application No. PCT/JP2012/002447, filed on Apr. 6, 2012.

(51) Int. Cl. H01L 29/10; H01L 29/417; H01L 29/45; H01L 29/78

(52) U.S. Cl. CPC H01L 29/1087; H01L 29/7816; H01L 29/41733; H01L 29/458
USPC 257/343

(57) ABSTRACT

There is provided a semiconductor device. An n-type transistor is formed on a (551) surface of a silicon substrate. A silicide layer region in contact with a diffusion region (heavily doped region) of the n-type transistor has a thickness not more than 5 nm. A metal layer region in contact with the silicide layer has a thickness of 25 nm (inclusive) to 400 nm (inclusive). A barrier height between the silicide layer region and the diffusion region has a minimum value in this thickness relationship.

This application is a continuation of International Patent Application No. PCT/JP2012/002447 filed on Apr. 6, 2012, the entire content of which is incorporated herein by reference.

### BACKGROUND OF THE INVENTION

1. Field of the Invention

The present invention relates generally to a semiconductor device, and particular to a semiconductor device having a transistor formed on the (551) surface of a silicon semiconductor substrate.

2. Description of the Related Art

Conventionally, transistors have enhanced the performance mainly by shortening a channel length L and thinning the gate insulating film. However, along with the decrease in the channel length L, the problem of variations in the transistor threshold has become conspicuous. In addition, along with the decrease in the thickness of the gate insulating film, an increase in the off leakage current has become problematic. That is, it is essential today to improve the performance of the transistor itself. In particular, reduction of the series resistance of a transistor is expected to yield a large effect for improving the performance, and several researches have recently been conducted.

The present inventors have also published a prior-art research in, for example, IEICE Technical Report, “Low Resistance Source/Drain Contacts with Low Schottky Barrier for High Performance Transistors” (SDM2010-157) (NPL 1). In NPL 1, the present inventors proposed a method of reducing the series resistance of the transistor, and implements a silicide having a Schottky barrier height (to also be abbreviated as “SBH” hereinafter) of 0.3 eV for a p⁺-type region and an n⁺-type region.

The components of the series resistance of the transistor include the resistance of the heavily doped layer region of the source/drain regions and the contact resistance between the heavily doped layer region and the silicide layer region. The impurity concentration of the heavily doped layer region is close to the theoretical value. Reduction of the resistance of the heavily doped layer region has shifted to the challenge upon the manufacturing process associated with how to maximize activation of an impurity. Reduction of the contact resistance between the heavily doped layer region and the silicide layer region essentially depends on how to reduce the barrier height between the silicide layer region and the heavily doped layer region, as described in NPL 1.

FIG. 1a shows the simulation result of the contact resistivity and the saturation drain current. FIG. 1a shows the contact resistivity dependence of the current driving capability (saturation drain current) per 1-μm width of a transistor having a channel length of 45 nm. FIG. 1b is a plan view showing the schematic arrangement of the transistor.

The contact width (the width in the same direction as the channel length direction) of each of the silicide regions of the source electrode and the drain electrode is 45 nm, and the electron/hole density of the source region/drain region is 2×10²⁰ cm⁻³. As is apparent, when the contact resistivity exceeds 1×10⁻⁹ Ωcm², the current driving capability lowers accordingly. Hence, how to reduce the contact resistivity to 1×10⁻⁹ Ωcm² or less is the factor to increase the current driving capability.

On the other hand, the silicide layer region is formed at the same time as the activation of the heavily doped layer region by providing a metal layer on the heavily doped layer region and performing annealing on it. Depending on the metal used for silicidation, the silicide in the formed silicide layer region may be oxidized, and the resistance may rise. To solve this problem, the present inventors have showed that a silicide layer region having a satisfactory contact resistivity can be formed by providing a second metal layer different from the silicidation metal, and more specifically, a tungsten (W) layer on the metal layer to be silicidized (for example, Japanese Patent Laid-Open No. 2010-109143 (PLT 1)).

### SUMMARY OF THE INVENTION

According to the first embodiment of the present invention, a semiconductor device comprises: an n-type transistor formed on a (551) surface of a silicon substrate, wherein a silicide layer region in contact with a diffusion region (heavily doped region) of the n-type transistor has a thickness not more than 8.5 nm, a metal layer region in contact with the silicide layer has a thickness of 25 nm (inclusive) to 400 nm (inclusive), and a barrier height between the silicide layer region and the diffusion region has a minimum value in this thickness relationship.

According to the second embodiment of a present invention, a semiconductor device has the n- type transistor formed on the (551) surface of silicon, wherein a silicide layer in contact with a diffusion region of the n-type transistor has a thickness of 2 nm (inclusive) to 8.5 nm (inclusive).

According to the third embodiment of a present invention, the silicide layer has a thickness of 2 nm (inclusive) to 8.5 nm (inclusive) in the semiconductor device according to the first embodiment.

Other features and advantages of the present invention will be apparent from the following descriptions taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1a is a schematic explanatory view for explaining the contact resistivity dependence of the current driving capability (saturation drain current) per 1-μm channel width of a transistor having a channel length of 45 nm;

FIG. 1b is a schematic explanatory view for explaining the contact resistivity dependence of the current driving capability (saturation drain current) per 1-μm channel width of the transistor having the channel length of 45 nm;

FIG. 2 is an explanatory view for explaining the relationship between the contact resistivity and the barrier height;

FIG. 3 is an explanatory view for explaining the film thickness dependence of the barrier height of erbium silicide formed on the (551) surface of n-type silicon;

FIG. 4 is a view showing the relationship between the thickness of tungsten (W) and the Schottky barrier height;

FIG. 5a is a schematic sectional explanatory view for explaining a manufacturing step a of a semiconductor device according to a preferable embodiment of the present invention by example;

FIG. 5b is a schematic sectional explanatory view for explaining a manufacturing step b of the semiconductor device according to the preferable embodiment of the present invention by example;

FIG. 5c is a schematic sectional explanatory view for explaining a manufacturing step c of the semiconductor device according to the preferable embodiment of the present invention by example;

FIG. 5d is a schematic sectional explanatory view for explaining a manufacturing step d of the semiconductor device according to the preferable embodiment of the present invention by example;

FIG. 5e is a schematic sectional explanatory view for explaining a manufacturing step e of the semiconductor device according to the preferable embodiment of the present invention by example;

FIG. 5f is a schematic sectional explanatory view for explaining a manufacturing step f of the semiconductor device according to the preferable embodiment of the present invention by example;

FIG. 5g is a schematic sectional explanatory view for explaining a manufacturing step g of the semiconductor device according to the preferable embodiment of the present invention by example;

FIG. 5h is a schematic sectional explanatory view for explaining a manufacturing step h of the semiconductor device according to the preferable embodiment of the present invention by example;

FIG. 5i is a schematic sectional explanatory view for explaining a manufacturing step i of the semiconductor device according to the preferable embodiment of the present invention by example;

FIG. 5j is a schematic sectional explanatory view for explaining a manufacturing step j of the semiconductor device according to the preferable embodiment of the present invention by example;

FIG. 5k is a schematic sectional explanatory view for explaining a manufacturing step k of the semiconductor device according to the preferable embodiment of the present invention by example;

FIG. 5l is a schematic sectional explanatory view for explaining a manufacturing step l of the semiconductor device according to the preferable embodiment of the present invention by example;

FIG. 5m is a schematic sectional explanatory view for explaining a manufacturing step m of the semiconductor device according to the preferable embodiment of the present invention by example; and

FIG. 5n is a schematic sectional explanatory view for explaining a manufacturing step n of the semiconductor device according to the preferable embodiment of the present invention by example.

### DESCRIPTION OF THE EMBODIMENTS

No matter whether in the technique of NPL 1 or that of PLT 1, there exist problems in no small numbers which need to be progressively subjected to research and development and solved from the practical point of view of transistors with ultimate performance.

The present invention has been made upon perceiving the above-described problems. Some emdodiments provide a technique advantageous for improving the operating speed of an integrated circuit.

Progressive and diligent studies solve the above-described problems to further improve the techniques of NPL 1 and PLT 1.

The present invention is based on research and development from such a viewpoint. Some embodiments provide a semiconductor device in which a lower barrier height is formed by setting the thickness of a second metal layer within a specific thickness range.

The present invention is based on findings in the course of the research and development about the facts that the barrier height is closely related with the thickness of the layer of the second metal such as tungsten, and the silicide formation metal and the second metal suitable for silicidation of the metal hold a relationship to minimize the barrier height.

According to some embodiments, the operating speed of the transistor dramatically improves. When forming an integrated circuit, the individual transistors constituting the integrated circuit have a uniform operating speed, and an integrated circuit suitable for a high-speed operation can be formed.

Special consideration is required for a silicide layer for an electrical contact formed on the (551) surface of a silicon substrate. In a silicide layer formed on the (551) surface of a silicon substrate in an n-type region, for example, an erbium silicide layer and a holmium silicide layer, the barrier height tends to be higher than in a palladium silicide layer formed on the (551) surface of the silicon in a p-type region, as pointed out by the present inventors in NPL 1 described above. In addition, a silicide layer formed on the (551) surface of the silicon substrate in the p-type region, for example, a palladium silicide layer cannot be even and coagulates unless it is thick to some extent, as pointed out by the present inventors in NPL 1 described above.

The above-described barrier height difference between the (100) surface and the (551) surface is assumed to occur because the surface density of silicon atoms is lowest at 6.8×10¹⁴ cm⁻² on the (100) surface of silicon but highest at 9.7×10¹⁴ cm⁻² on the (551) surface. The atomic radii of silicon (Si), palladium (Pd), erbium (Er), and holmium (Ho) are 0.117 nm, 0.13 nm, 0.175 nm, and 0.174 nm, respectively. As indicated by these numerical values, erbium and holmium atoms have very large radii. When a silicide layer is formed using erbium or holmium on the (551) surface of the silicon substrate with a high atomic surface density, very large stress occurs. This stress probably raises the barrier height of the silicide formed on the (551) surface.

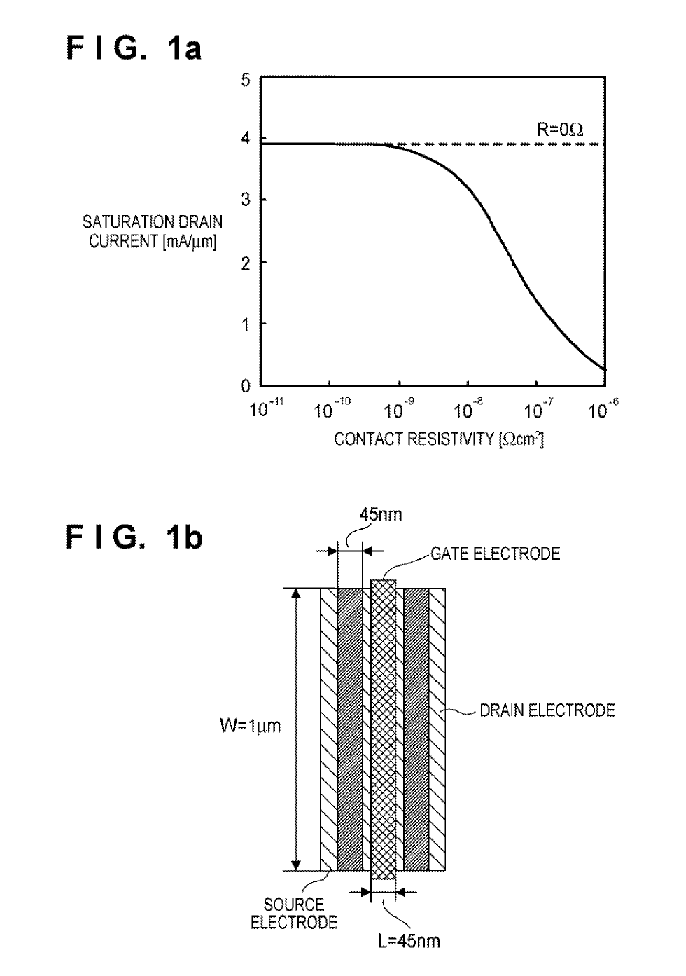

FIG. 1a illustrates the contact resistivity dependence of the current driving capability (saturation drain current) per 1-μm channel width of a transistor having a channel length of 45 nm. FIG. 1b is a schematic plan view showing the schematic arrangement of the transistor. The contact width (the width in the same direction as the channel length direction) of each of the silicide layers of the source electrode and the drain electrode is 45 nm, and the electron/hole density of the source region/drain region is 2×10²⁰ cm³. As is apparent, when the contact resistivity exceeds 1×10⁻⁹ Ωcm², the current driving capability lowers accordingly.

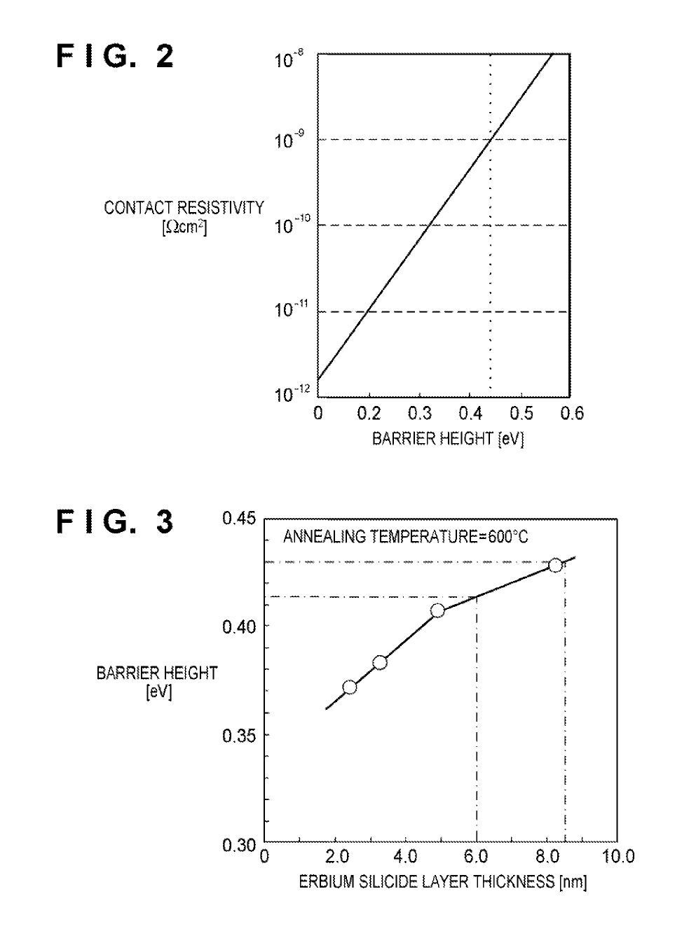

FIG. 2 illustrates a barrier height necessary to implement a contact resistivity of 1×10⁻⁸ Ωcm² to 1×10⁻¹¹ Ωcm². The electron/hole density is 2×10²⁰ cm⁻³. To implement a contact resistivity of 1×10⁻⁹ Ωcm², the barrier height needs to be 0.43 eV or less.

FIG. 3 illustrates the film thickness dependence of the barrier height (barrier height with respect to n-type silicon) of an erbium silicide formed on the (551) surface of an n-type silicon substrate. Note that the annealing temperature for silicidation of erbium was set to 600° C. As the erbium silicide layer thins, the barrier height decreases. When the erbium silicide layer is 2.5 nm thick, the barrier height is 0.37 eV.

To implement a contact resistivity of 1×10⁻⁹ Ω cm² and further improve the current driving capability of the transistor, the barrier height of 0.43 eV or less is obtained by setting the thickness of the erbium silicide layer to 8.5 nm or less. It was experimentally confirmed that when the thickness of the erbium silicide layer is smaller than 2 nm, no excellent erbium silicide layer can be formed. The reason for this still remains in the realm of speculation. Realistically, it was experimentally confirmed that when the thickness is 2.5 nm or more, the erbium silicide layer can be formed stably and reproducibly.

As for the upper limit of the thickness, an erbium silicide layer too thick is not preferable from the viewpoint of production efficiency. If the erbium silicide layer is too thick, the distortion of the layer itself exerts an influence, leading to a tendency to difficulty in forming an appropriate barrier height. Experimental examinations reveal that the upper limit of the thickness of the erbium silicide layer is 8.5 nm when the upper limit of the barrier height is allowed to be 0.43 eV.

In the present embodiment, the thickness of the erbium silicide layer is appropriately selected in consideration of the above-described points. The erbium silicide layer is formed on the (551) surface of an n-type silicon substrate to the thickness of preferably 2 nm (inclusive) to 8.5 nm (inclusive), more preferably, 2.5 nm (inclusive) to 6 nm (inclusive), and still more preferably, 2.5 nm (inclusive) to 4 nm (inclusive).

In the present embodiment, when forming a silicide layer region using a metal such as erbium, a refractory metal layer is formed in contact with a heavily doped region (diffusion region) in advance for the silicide layer region formation. The refractory metal layer assists forming a satisfactory electrical contact between the heavily doped region and the silicide layer region by relaxing or preventing distortion that occurs in the silicide layer region when annealing is performed to make the metal in the silicide formation metal layer and silicon in the heavily doped region dissolve with each other to form the silicide layer region. As a result, the barrier height formed between the heavily doped region and the silicide layer region is lower than in a case in which no refractory metal layer is provided, and the current driving capability of the formed transistor considerably improves.

As the metal used to form the refractory metal layer, a metal that does not dissolve or mix with the metal contained in the silicide layer region upon annealing is preferably selected. In addition, a metal that has excellent heat resistance and also provides an excellent oxygen permeation inhibition capability such that the silicide layer region does not oxidize due to the influence of heat during silicidation annealing or another annealing process is selected. In the present embodiment, tungsten (W) is employed as this refractory metal.

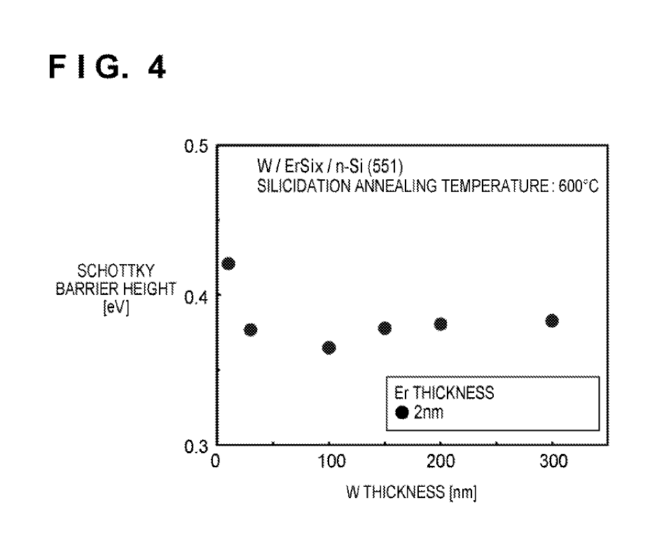

FIG. 4 shows experimental data representing the relationship between the thickness of tungsten (W) and the Schottky barrier height (to also be referred to as “SBH” hereinafter). The thickness of erbium (Er) when forming the silicide layer is 2 nm. The result was obtained forming six samples each having an erbium (Er) film formed on the (551) surface of an n-type silicon substrate and a tungsten (W) layer having a predetermined thickness formed on it and measuring the SBH of each sample. The silicidation annealing temperature of each sample was set to 600° C.

The thickness of the tungsten (W) layer and SBH of each sample are as follows.

TABLE 1

| Sample No. | W layer thickness (nm) | SBH (eV) |
|---|---|---|
| 101 | 300 | 0.383 |
| 102 | 200 | 0.381 |
| 103 | 150 | 0.378 |
| 104 | 100 | 0.365 |
| 105 | 30 | 0.377 |
| 106 | 10 | 0.421 |

This result shows that to obtain a barrier height of 0.43 eV or less, the thickness of the tungsten (W) layer needs to be 10 nm or more, and the practical upper limit is preferably 300 nm. In addition, according to the experiments of the present inventors, the SBH has the minimum value when the thickness of the tungsten (W) layer is 25 nm to 150 nm, and the upper limit of the thickness of the tungsten (W) layer is more preferably 150 nm or less considering that a lower SBH can be formed.

The above-described points also apply even when a silicide layer of holmium having an almost the same atomic radius as erbium is formed on the (551) surface of the n-type silicon substrate in place of the erbium silicide layer.

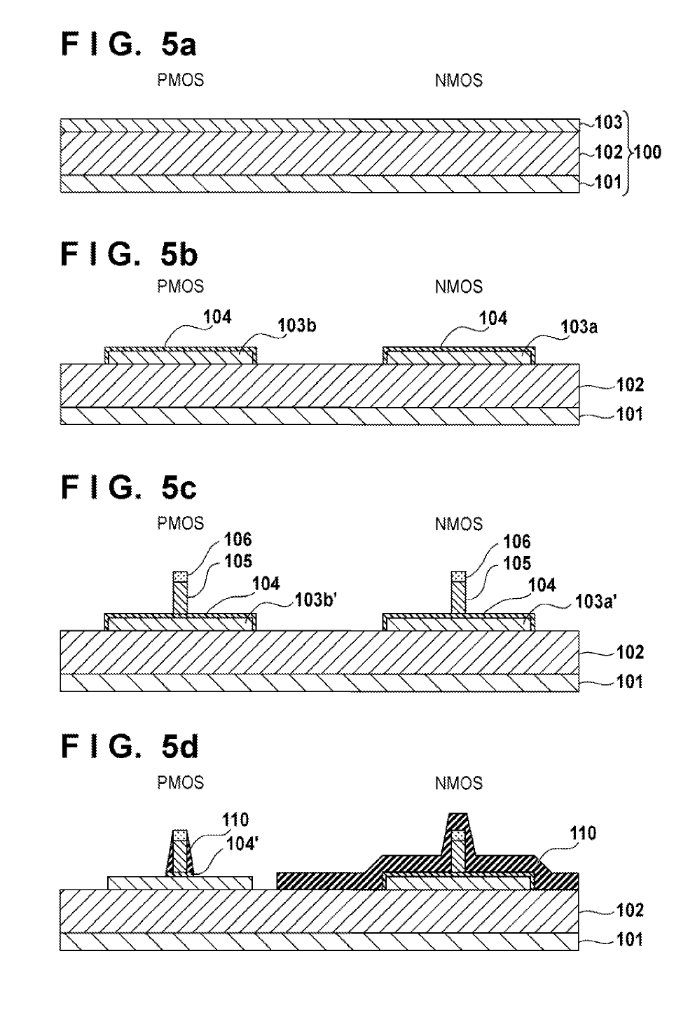

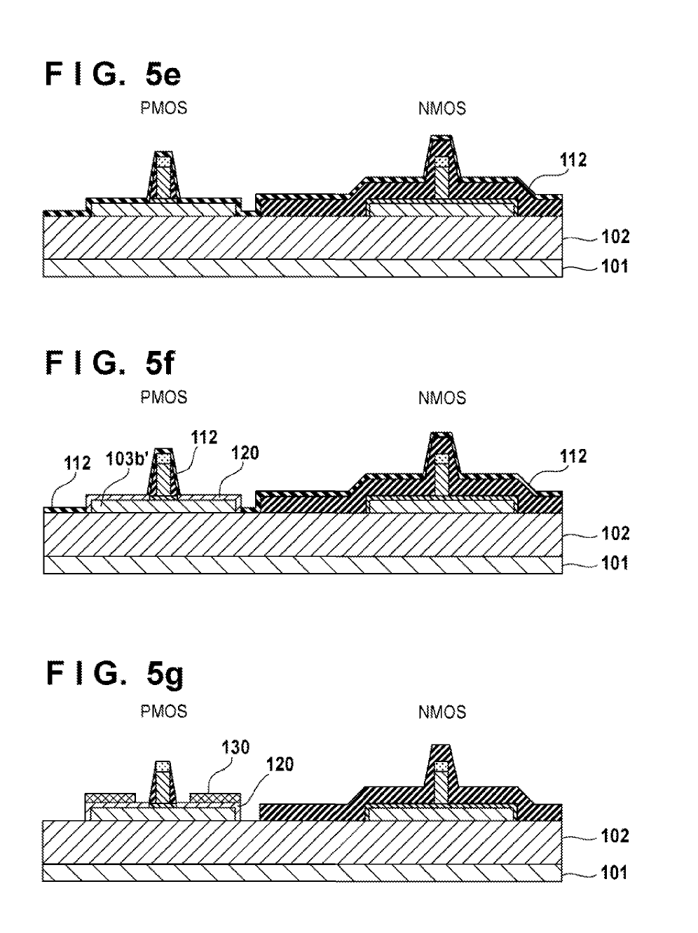

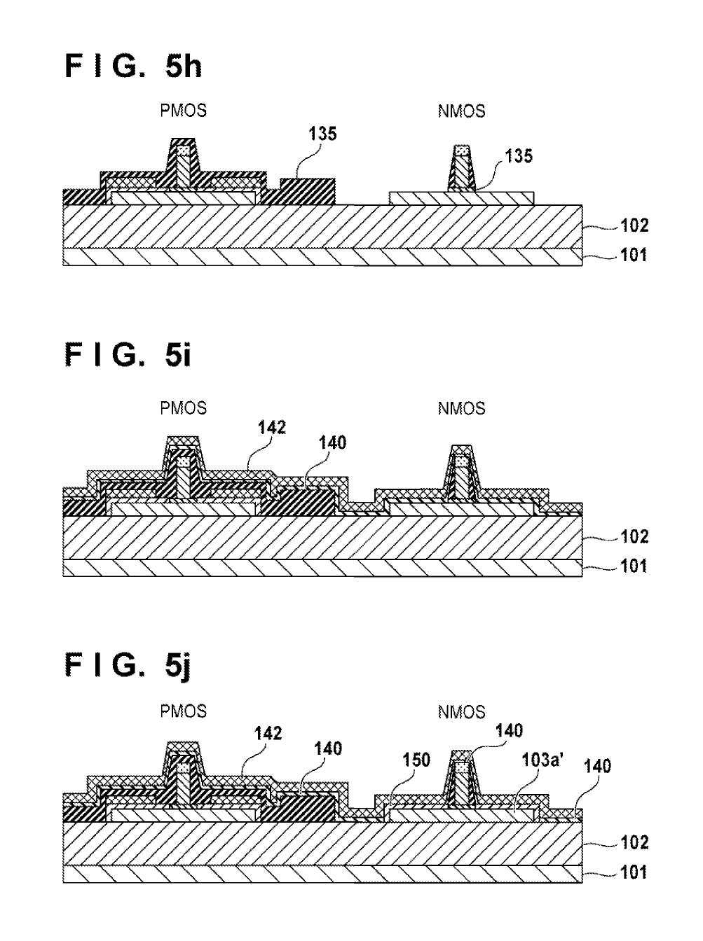

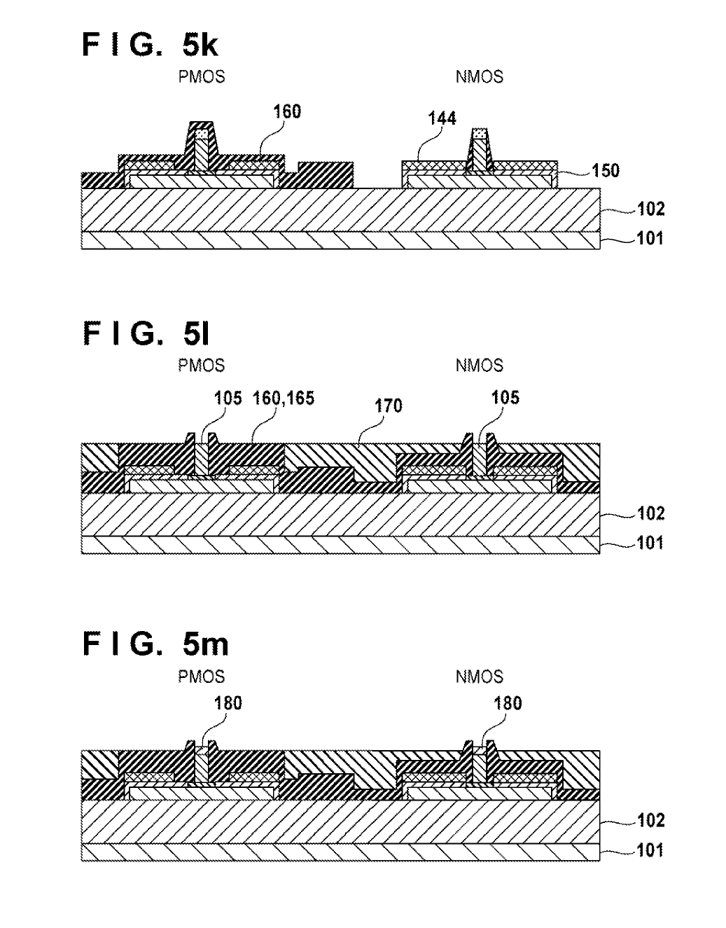

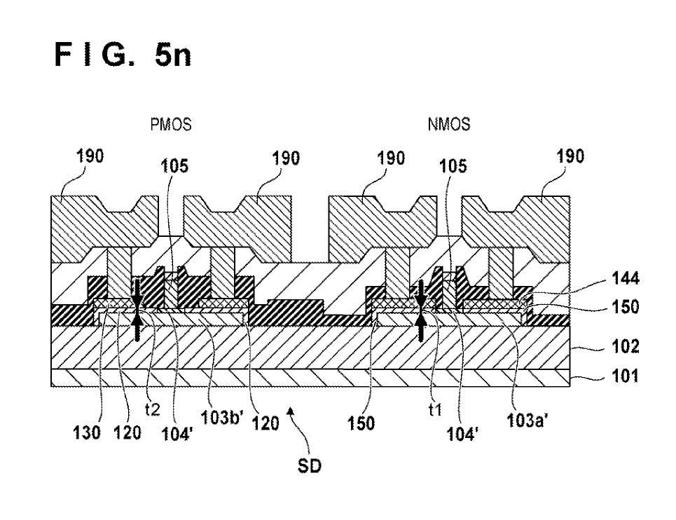

FIG. 5a to 5n are schematic sectional explanatory views for explaining the manufacturing steps (steps a to n) of a semiconductor device according to a preferable embodiment of the present invention by example. FIG. 5n schematically illustrates the sectional arrangement of a semiconductor device SD according to the preferred embodiment of the present invention which is manufactured by the manufacturing steps.

A method of manufacturing the semiconductor device SD according to the preferred embodiment of the present invention will be described below with reference to FIG. 5a to 5n. Referring to FIG. 5a to 5n, “NMOS” indicates a region where an NMOS transistor is formed or an NMOS transistor, and “PMOS” indicates a region where a PMOS transistor is formed or a PMOS transistor.

In the step shown in FIG. 5a, an SOI (Silicon On Insulator) substrate 100 is prepared. The SOI substrate 100 includes an insulator 102 on a silicon region 101, and an SOI layer (silicon region) 103 on the insulator 102. The surface of the SOI layer 103 is the (551) surface.

In the step shown in FIG. 5b, boron ions are implanted in a region out of the SOI layer 103 where an NMOS transistor is to be formed, and antimony ions are implanted in a region out of the SOI layer 103 where a PMOS transistor is to be formed. After that, activation annealing is performed. A p-type well 103a is thus formed in the region where the NMOS transistor is to be formed, and an n-type well 103b is formed in the region where the PMOS transistor is to be formed. Next, the SOI layer 103 is patterned by dry etching such as microwave plasma dry etching. Then, the surfaces of the p-type well 103a and the n-type well 103b are oxidized by an oxidation method such as radical oxidation to form a silicon oxide film used to form a gate insulating film. The silicon oxide film is assumed to have a thickness of, for example, 3 nm. The thickness is appropriately set as desired.

In the step shown in FIG. 5c, an undoped polysilicon film used to form a gate electrode is formed by a deposition method such as LPCVD (Low Pressure Chemical Vapor Deposition). The polysilicon film can have a thickness of, for example, 150 nm. After that, an oxide film is formed by a deposition method such as APCVD (Atmospheric Pressure Chemical Vapor Deposition) and patterned to form a hard mask 106. The oxide film or the hard mask 106 can have a thickness of, for example, 100 nm. Next, the polysilicon film is etched by dry etching such as microwave plasma dry etching to form gate electrodes 105. Then, arsenic ions are implanted in the p-type well 103a where the NMOS transistor is to be formed, and boron ions are implanted in the n-type well 103b where the PMOS transistor is to be formed. After that, activation annealing is performed to form source regions and drain regions. The p-type well 103a where the source region and the drain region are formed will be referred to as a diffusion region 103a′, and the n type well 103b where the source region and the drain region are formed as a diffusion region 103b′ hereinafter for the sake of convenience.

In the step shown in FIG. 5d, a silicon nitride film is formed by a deposition method such as ME-PECVD (Microwave Excited Plasma Enhanced Chemical Vapor Deposition). The silicon nitride film can have a thickness of, for example, 20 nm. After that, only in the region where the PMOS transistor is to be formed, the silicon nitride film is removed by dry etching such as microwave plasma dry etching. In addition, the silicon oxide film on the source region and the drain region in the region where the PMOS transistor is to be formed is removed by a diluted hydrofluoric acid (HF) solution.

In the step shown in FIG. 5e, a palladium film 112 is formed by sputtering. The palladium film 112 can have a thickness of, for example, 7.5 nm.

In the step shown in FIG. 5f, silicidation annealing is performed. The palladium film 112 and silicon in the diffusion region 103b′ thus react to form a palladium silicide layer 120. The palladium silicide layer 120 can have a thickness of, for example, 11 nm. In this silicidation annealing, no reaction occurs on the silicon oxide film or silicon nitride film, and only the source region and the drain region of the PMOS transistor are silicidized.

In the step shown in FIG. 5g, a tungsten film (metal film) is formed by sputtering so as to have a thickness of for example, 100 nm. The tungsten film is wet-etched so that the portions of the source region and the drain region of the PMOS transistor remain. After that, the unreacted palladium film 112 is removed by wet etching. The tungsten film is thus patterned to form metal electrodes (tungsten electrodes) 130 in contact with the palladium silicide layer 120. At this time, the tungsten film can be etched to a thickness of, for example, about 50 nm.

In the step shown in FIG. 5h, a silicon nitride film 135 is formed by a deposition method such as ME-PECVD (Microwave Excited Plasma Enhanced Chemical Vapor Deposition). The silicon nitride film can have a thickness of, for example, 20 nm. After that, only in the region where the NMOS transistor is to be formed, the silicon nitride film is removed by dry etching such as microwave plasma dry etching. In addition, the silicon oxide film on the source region and the drain region in the region where the NMOS transistor is to be formed is removed by a diluted hydrofluoric acid (HF) solution.

In the step shown in FIG. 5i, an erbium film 140 and a tungsten film (metal film) 142 are sequentially formed by sputtering. The erbium film 140 can have a thickness of, for example, 2 nm. The tungsten film 142 can have a thickness of, for example, 100 nm.

In the step shown in FIG. 5j, silicidation annealing is performed. The erbium film 140 and silicon in the diffusion region 103a′ thus react to form an erbium silicide layer 150. The erbium silicide layer 150 can have a thickness of, for example, 3.3 nm. In this silicidation annealing, no reaction occurs on the silicon oxide film or silicon nitride film, and only the source region and the drain region of the NMOS transistor are silicidized. In the above-described way, silicide layers of different materials and thicknesses are formed on the source regions and the drain regions of the PMOS and NMOS transistors.

In the step shown in FIG. 5k, the tungsten film 142 and the unreacted erbium film 140 are removed by wet etching so that the portions of the source region and the drain region of the NMOS transistor remain. Metal electrodes (tungsten electrodes) 144 in contact with the erbium silicide layer 150 are thus formed on the source region and the drain region of the NMOS transistor.

In the step shown in FIG. 51, a silicon nitride film 165 is deposited to a thickness of, for example, 20 nm by a deposition method such as ME-PECVD (Microwave Excited Plasma Enhanced Chemical Vapor Deposition). In addition, an oxide film 170 for smoothing is deposited to a thickness of for example, 400 nm. After that, the hard mask (oxide film) 106 is etched together with the oxide film 170 by dry etching such as microwave plasma dry etching to expose the upper surfaces of the gate electrodes 105.

In the step shown in FIG. 5m, a palladium film is deposited to a thickness of, for example, 10 nm by sputtering. Silicidation annealing is performed to silicidize the palladium film. At this time, no silicidation reaction occurs on the silicon oxide film, the smoothing oxide film, and the silicon nitride film. Silicidation reaction occurs only in the palladium film on the gate electrodes 105, and a palladium silicide layer 180 is formed. After that, the unreacted palladium film is removed by wet etching.

In the step shown in FIG. 5n, a silicon oxide film having a thickness of, for example, 300 nm is formed as an interlayer dielectric film by APCVD (Atmospheric Pressure Chemical Vapor Deposition). Contact holes are formed by dry etching such as microwave plasma dry etching. After that, aluminum is deposited by a deposition method such as vapor deposition or sputtering and patterned by dry etching such as microwave plasma dry etching, thereby forming electrodes. With the above-described steps, the semiconductor device SD having the arrangement as schematically illustrated in FIG. 5n is obtained. The semiconductor device is completed by a normal interconnection process and the like hereafter.

The semiconductor device SD formed by the above-described steps has an arrangement with n- and p-type transistors formed on the (551) surface of the silicon substrate.

In the present invention, expression “the transistor is formed on the (551) surface” means that some (for example, gate oxide film) of the elements of the transistor are formed on the (551) surface. The n-type transistor can typically be an NMOS transistor, and the p-type transistor can typically be a PMOS transistor. The arrangement shown in FIG. 5n can also be understood as the basic arrangement of a CMOS circuit.

An example has representatively been described above in which the n-type transistor is an NMOS transistor, and the p-type transistor is a PMOS transistor. However, this does not intend that the present invention is limited to this arrangement.

The NMOS transistor includes, for example, the diffusion regions 103a′ including the source region and the drain region, the silicide layers 150, 150 in contact with the source region and the drain region in the diffusion region 103a′, the metal electrodes 144, 144 in contact with the upper surfaces of the silicide layers 150, 150, a gate insulating film 104′, and the gate electrode 105. The silicide layer 150 and the metal electrode 144 form a contact portion to the diffusion region 103a′. The PMOS transistor includes, for example, the diffusion regions 103b′ including the source region and the drain region, the silicide layers 120, 120 in contact with the source region and the drain region in the diffusion region 103b′, the metal electrodes 130, 130 in contact with the upper surfaces of the silicide layers 120, 120, the gate insulating film 104′, and the gate electrode 105. The silicide layer 120 and the metal electrode 130 form a contact portion to the diffusion region 103b′. The diffusion regions 103a′ and 103b′ may be formed on the insulator 102, as illustrated in FIG. 5a to 5n, or in a silicon region (for example, silicon substrate, epitaxial layer, or well).

A thickness t1 of the silicide layers 150 of the NMOS transistor is preferably smaller than a thickness t2 of the silicide layers 120 of the PMOS transistor. The thickness t2 of the silicide layers 120 of the PMOS transistor is preferably, for example, 10 nm or more.

In the present invention, the (551) surface means not only the physically strict (551) surface but includes also a surface having an off angle of 4° or less with respect to the physically strict (551) surface.

Note that at the current point of time, to clarify the difference from an unknown related art, the present inventors may limit the definition of the (551) surface to a surface having an off angle equal to or smaller than an arbitrary angle such as 3° or less, 2° or less, 1° or less, or 0.5° or less with respect to the physically strict (551) surface after patent application.

The present invention is not limited to the above embodiments and various changes and modifications can be made within the spirit and scope of the present invention. Therefore, to apprise the public of the scope of the present invention, the following claims are made.

### REFERENCE SIGNS LIST

100 . . . SOI substrate

101 . . . silicon region

102 . . . insulator

103 . . . SOI layer

103a . . . n-type well

103b . . . p-type well

103a′, 103b′. . . diffusion region

104 . . . gate insulating film

105 . . . gate electrode

106 . . . hard mask

112 . . . palladium film

120 . . . palladium silicide layer

130 . . . metal electrode

135 . . . silicon nitride film

140 . . . erbium film

142 . . . tungsten film

144 . . . metal electrode

150 . . . erbium silicide layer

165 . . . silicon nitride film

170 . . . oxide film

180 . . . palladium silicide layer

What is claimed is:

1. A semiconductor device comprising:
an n-type transistor formed on a (551) surface of a silicon substrate, wherein a silicide layer region in contact with a diffusion region (heavily doped region) of the n-type transistor has a thickness not more than 8.5 nm, a metal layer region in contact with the silicide layer has a thickness of 25 nm (inclusive) to 400 nm (inclusive), and a barrier height between the silicide layer region and the diffusion region has a minimum value in this thickness relationship.

2. The semiconductor device according to claim 1, wherein the silicide layer has a thickness of 2 nm (inclusive) to 8.5 nm (inclusive).

3. The semiconductor device according to claim 1, wherein the silicide layer in contact with the diffusion region of the n-type transistor is made essentially of one of erbium silicide and holmium silicide.
